(19) United States
(12) Patent Application Publication
(10) Pub. No.: US 2026/0082877 A1
(43) Pub. Date: Mar. 19, 2026

(54) SEMICONDUCTOR DEVICE AND FABRICATION METHODS THEREOF

(71) Applicant: Yangtze Memory Technologies Co., Ltd., Wuhan (CN)

(72) Inventors: Bingguo WANG, Wuhan (CN); Zhen XIE, Wuhan (CN); Chao FANG, Wuhan (CN)

(21) Appl. No.: 18/923,103

(22) Filed: Oct. 22, 2024

Related U.S. Application Data
(63) Continuation of application No. PCT/CN2024/119286, filed on Sep. 18, 2024.

(51) Int. Cl. H01L 21/763; H10B 43/10; H10B 43/20

(52) U.S. Cl. CPC H10W 10/40; H10B 43/10; H10B 43/20; H10W 10/041

(57) ABSTRACT

The present disclosure relates to methods, devices, systems, and techniques for managing isolating structures in semiconductor devices. An example semiconductor device includes a first stack of conductive layers and isolating layers alternating with each other along a first direction. An isolating structure that extends through the stack along the first direction. The isolating structure includes an inner body, filled with at least one semiconductor material extending continuously along the first direction, and an outer layer, filled with an isolating material, that is at least partially between the inner body and the stack along a second direction.

### CROSS-REFERENCE TO RELATED APPLICATIONS

This application is a continuation of International Application No. PCT/CN2024/119286, filed on Sep. 18, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing contact structures in semiconductor devices.

One aspect of the present disclosure features a semiconductor device. The semiconductor device includes a stack of conductive layers and isolating layers alternating with each other along a first direction; and an isolating structure that extends through the stack along the first direction, where the isolating structure includes an inner body and an outer layer that is at least partially between the inner body and the stack along a second direction perpendicular to the first direction, where the outer layer of the isolating structure includes an isolating material, and where the inner body has a first end and a second end that are opposite to each other along the first direction, and the inner body is filled with at least one semiconductor material extending continuously along the first direction.

In some implementations, the at least one semiconductor material filled in the inner body has a polycrystalline structure, and where the at least one semiconductor material extends seamlessly along the first direction.

In some implementations, the semiconductor device further including at least one additional layer stacked with the stack along the first direction, where the isolating structure extends into the at least one additional layer along the first direction, where the outer layer includes a first portion and a second portion along the first direction, the first portion being closer to the first end than the second end of the inner body, and where the first portion of the outer layer is between the inner body and the at least one additional layer along the second direction, and the second portion of the outer layer is between the inner body and the stack along the second direction.

In some implementations, along the second direction, a thickness of the first portion of the outer layer is greater than a thickness of the second portion of the outer layer.

In some implementations, the at least one semiconductor material is an alloy of two or more semiconductor materials.

In some implementations, the alloy includes Silicon-Germanium (SiGe), and where the inner body includes a core region and a transition region, where at least a portion of the transition region is at the first end of the inner body, where a concentration of Silicon (Si) in the alloy in the transition region is greater than a concentration of Silicon (Si) in the alloy in the core region.

In some implementations, in the core region, a concentration of Germanium (Ge) in the alloy is greater than 80%, and the concentration of Silicon (Si) in the alloy is smaller than 20%, and wherein, in the transition region, a concentration of Silicon (Si) in the alloy is in a range between 20% and 28%.

In some implementations, the transition region has one or more characteristics including: a thickness of the transition region along the second direction being associated with a dimension of the isolating structure, and a length of the transition region of the inner body along the first direction being associated with a dimension of the isolating structure.

In some implementations, the semiconductor device further includes a channel structure extending through the stack along the first direction, the isolating structure being spaced from the channel structure along the second direction, wherein, along the first direction, an end of the channel structure is farther from the stack than an end of the isolating structure.

In some implementations, the channel structure is coupled to a conductive structure through a coupling-out structure from a bottom of the semiconductor device closer to the first end than the second end.

In some implementations, the semiconductor device further includes at least one semiconductor layer and one dielectric layer that are stacked with the stack along the first direction, where the channel structure is coupled to a conductive structure through a coupling-out structure through the semiconductor layer along the second direction.

Another aspect of the present disclosure features a method of forming a semiconductor device. The method includes forming a stack of conductive layers and isolating layers alternating with each other along a first direction; and forming an isolating structure that extends through the stack along the first direction, where the isolating structure includes an inner body and an outer layer that is at least partially between the inner body and the stack along a second direction perpendicular to the first direction, where the outer layer of the isolating structure includes an isolating material, and where the inner body has a first end and a second end that are opposite to each other along the first direction, and the inner body is filled with at least one semiconductor material extending continuously along the first direction.

In some implementations, the method further includes providing an initial stack of dielectric layers and isolating layers alternating with each other on a semiconductor substrate along the first direction; etching through the initial stack into the semiconductor substrate along the first direction to from a trench, where a first portion of the trench extends in the semiconductor substrate along the second direction, and a second portion of the trench extends in the stack along the second direction; forming a first dielectric layer in the semiconductor substrate by thermal oxidation, where the first dielectric layer is in contact with the first portion of the trench; and forming conductive layers of the stack by replacing the dielectric layers of the initial stack with a conductive material.

In some implementations, the method further includes depositing a second dielectric layer on a sidewall of the trench, where the second dielectric layer is deposited on the first dielectric layer to form the outer layer, where a first portion of the outer layer is between the trench and semiconductor substrate along the second direction, and a second portion of the outer layer is between the trench and the stack along the second direction, and wherein, along the second direction, a thickness of the second portion of the outer layer is greater than a thickness of the first portion of the outer layer.

In some implementations, the at least one semiconductor material is an alloy of two or more semiconductor materials, and where the method further includes: depositing one of the semiconductor materials of the alloy in the trench to form a semiconductor layer; filling the first trench with a photoresist material; removing a portion of the photoresist material in the trench to expose a portion of the semiconductor layer; etching the exposed portion of the semiconductor layer in the trench; and removing a remaining portion of the photoresist material in the trench to form a seed layer, where at least a portion of the seed layer is at the an end of the outer layer, and where the seed layer is closer to the semiconductor substrate than a surface of the stack along the first direction.

In some implementations, forming the isolating structure includes: forming the inner body by growing the alloy in the trench from the seed layer to the surface of the stack, where the alloy filled in the trench has a polycrystalline structure.

In some implementations, growing the alloy includes: depositing the alloy in the trench by low pressure chemical vapor deposition (LPCVD) process, where the alloy is diffused into the seed layer during the LPCVD process to form a transition region of the inner body, and where at least a portion of the transition region is at the first end of the inner body.

In some implementations, a selectivity of the alloy to grow on the seed layer is higher than a selectivity of the alloy to grow on the outer layer of the isolating structure.

In some implementations, the method further includes forming a channel structure extending through the stack along the first direction, where the isolating structure is spaced from the channel structure along the second direction, and wherein, along the first direction, an end of the channel structure is farther from a surface of the stack than an end of the isolating structure.

A further aspect of the present disclosure features a memory system. The memory system includes a memory device and a memory controller coupled to the memory device and configured to control the memory device. The memory device includes a stack of conductive layers and isolating layers alternating with each other along a first direction; and an isolating structure that extends through the stack along the first direction, where the isolating structure includes an inner body and an outer layer that is at least partially between the inner body and the stack along a second direction perpendicular to the first direction, where the outer layer of the isolating structure includes an isolating material, and where the inner body has a first end and a second end that are opposite to each other along the first direction, and the inner body is filled with at least one semiconductor material extending continuously along the first direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF DRAWINGS

FIG. 1 illustrates a top view of an example semiconductor device.

FIG. 2A - 2C illustrate cross-section view of example semiconductor devices.

FIGS. 3A-3H illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to the demand for cheaper memory devices with higher density, a memory device (e.g., a 3D NAND flash memory) can be formed with a large number of layers and a high aspect ratio. The large number of layers and the high aspect ratio of such memory devices may bring challenges to the manufacturing process. For example, the fabrication of the large number of layers requires a deep gate line slit structure, which leads to a severe stress issue that causes the X-Y bow problem in the semiconductor stack. In other words, the conductive layers may bend during the fabrication of the memory device. Additionally, seams may form during the filling of the gate line slit structure due to the increased device depth. These seams in the filling may lead to substrate cracking during the later stages of fabrication. Therefore, fabrication methods that can solve the aforementioned issues are desirable.

In one or more implementations of the present disclosure, an example semiconductor device is provided. The semiconductor device includes a stack of conductive layers and isolating layers alternating with each other along a first direction. The semiconductor device further includes an isolating structure that extends through the stack along the first direction, where the isolating structure includes an inner body and an outer layer that is at least partially between the inner body and the stack along a second direction perpendicular to the first direction. The outer layer of the isolating structure includes an isolating material, and the inner body has a first end and a second end that are opposite to each other along the first direction, and the inner body is filled with at least one semiconductor material extending continuously along the first direction.

Implementations of the present disclosure can provide one or more of the following technical advantages and/or benefits. First, in the example semiconductor device described above, a seed layer at the bottom of the isolating structure is used to assist the formation of the isolating structure. A selectivity of the at least one semiconductor material to form on the seed layer is higher than a selectivity of the at least one semiconductor material to form on the outer layer. In other words, the formation of the at least one semiconductor filling in the isolating structure is a top-up growth from the bottom. Thus, the at least one semiconductor filling extends continuously and seamlessly along a vertical direction, mitigating the cracking problem during the fabrication process. Second, the polycrystalline structure of the at least one semiconductor material can relieve stress during the fabrication process, which mitigates the X-Y bow problem in the semiconductor stack.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

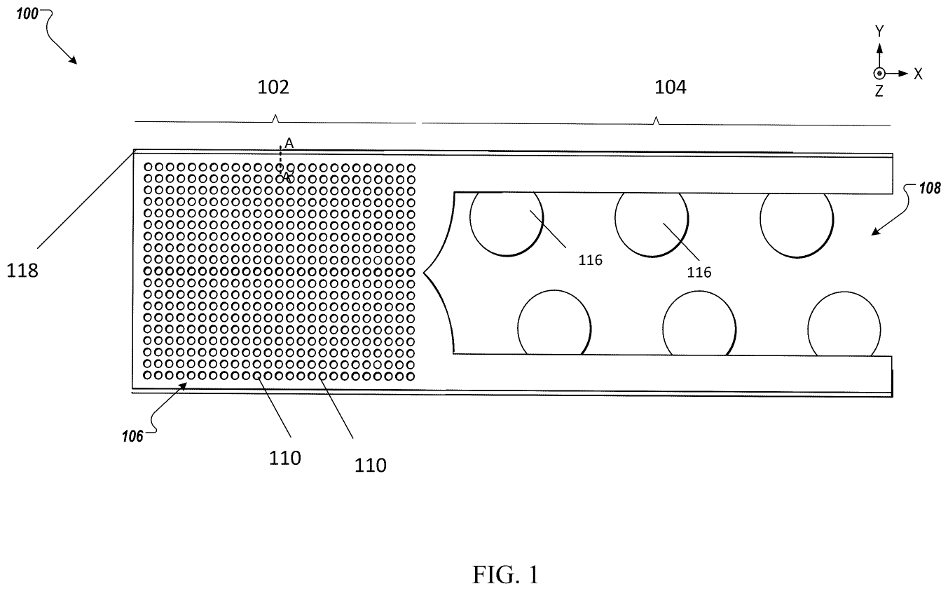

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used in the present disclosure, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

FIG. 1 illustrates a top view of an example semiconductor device 100. In some implementations, the semiconductor device 100 can be a memory device, such as a three-dimensional (3D) NAND memory device. The semiconductor device 100 can include one or more array regions and one or more connection regions configured to provide conductive connections for the one or more array regions. In some implementations, as shown in FIG. 1, the semiconductor device 100 includes an array region 102 and a connection region 104 adjacent to the array region 102 along a first horizontal direction (e.g., the X direction). It is understood that the example in FIG. 1 is for illustration purpose and is not intended to be construed in a limiting sense. In practice, any suitable arrangement of various regions in the semiconductor device 100 can be applied. In some instances, the semiconductor device 100 can have two connection regions 104 and an array region 102 arranged between the two connection regions 104 along the X direction. In some other instances, the semiconductor device 100 can have two array regions 102 and a connection region 104 between the two array regions 102 along the X direction. In some implementations, the connection region 104 has a staircase structure for padding out the conductive layers in the array regions 102.

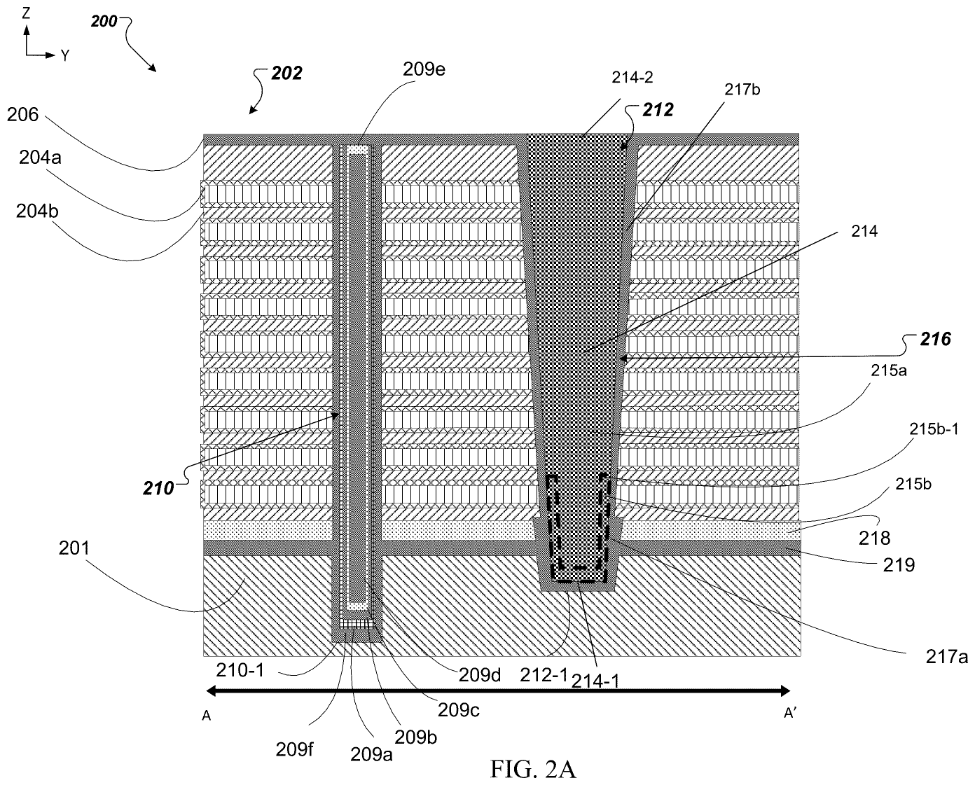

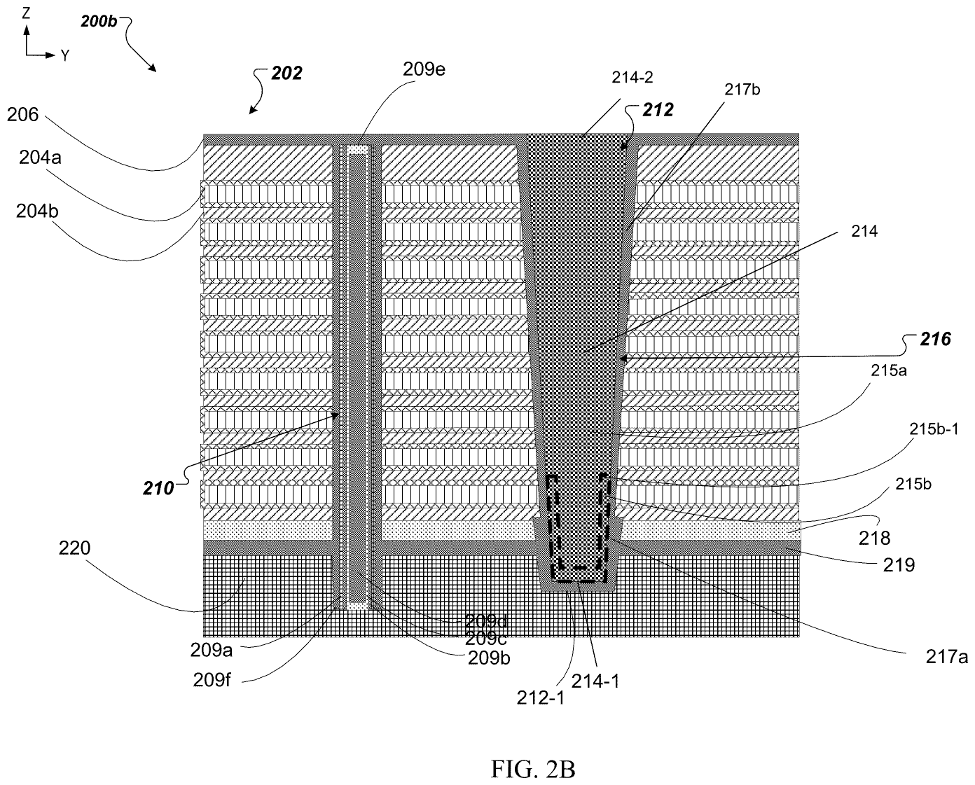

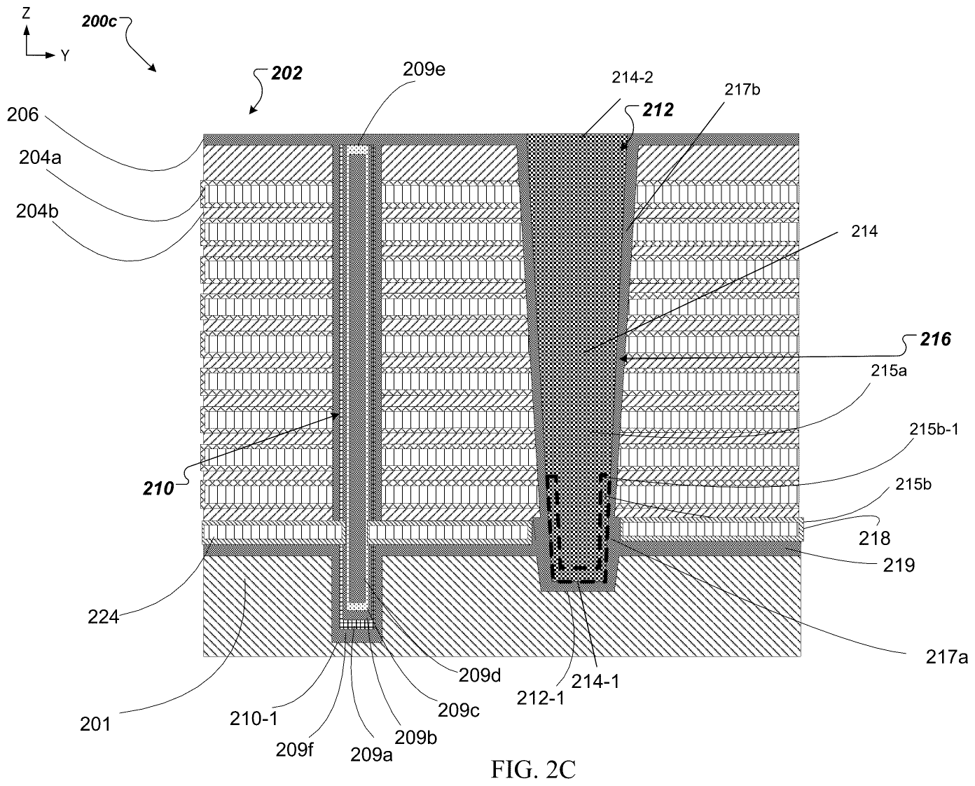

The semiconductor device 100 includes a stack 106 of alternating conductive layers and isolating layers (e.g., conductive layers 204a and isolating layers 204b as shown in FIG. 2A). In some implementations, a part of the stack 106 can be in the array region 102, and another part of the stack 106 can be in the connection region 104. The semiconductor device 100 further includes a stack 108 of alternating dielectric layers and isolating layers. In some implementations, the stack 108 can be in the connection region 104. The stack 106 is connected to the stack 108. In some implementations, the stack 108 can include a staircase structure for padding out the conductive layers of the stack 106 of the array region 102. The staircase structure has one or more stairs corresponding to the one or more conductive layers 204a of the stack 106. For example, the number of stairs is equal to the number of the conductive layers 204a of the stack 106.

The semiconductor device 100 can include an array of channel structures 110 extending through the stack 106 in the array region 102. Each channel structure 110 can be used to form a string of memory cells coupled in serial along a vertical direction (e.g., Z direction) perpendicular to the first horizontal direction (e.g., the X direction). The semiconductor device 100 can include contact structures 116 in the connection region 104. A contact structure 116 can be configured to connect a corresponding one of the conductive layers of the stack 106 to a control circuit. The semiconductor device 100 can include one or more gate line slit structures 118. Each gate line slit structure 118 can extend in the X direction. The gate line slit structure 118 can extend into both the array region 102 and the connection region 104. In some implementations, the gate line slit structures 118 can divide an array region into multiple memory blocks. In some implementations, the gate line slit structure 118 can function as a common source contact for the channel structures 110 in the array region 102. In some implementations (not shown in FIG. 1), the gate line slit structure 118 can further include one or more segments extending along a second horizontal direction (e.g., the Y direction). In some implementations, the gate line slit structure 118 can include multiple segments connected in an H shape or a T shape.

FIG. 2A illustrates a cross-sectional view of the semiconductor device 200 along cut line AA′ of FIG. 1. The semiconductor device 200 can be the semiconductor device 100 of FIG. 1 or a structure at an intermediate fabrication process of the semiconductor device 100 of FIG. 1.

As shown in FIG. 2A, the semiconductor device includes a substrate 201, the stack 202 of alternating conductive layers 204a and isolating layers 204b. The stack 202 is provided over the substrate 201. The substrate 201 can be any suitable semiconductor substrate having any suitable semiconductor material, such as monocrystalline, polycrystalline or single crystalline semiconductor. For example, the substrate 201 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. In some implementations, the substrate 201 can be removed from the semiconductor device 200 in a later process of manufacturing the semiconductor device 200. The semiconductor device 200 can include a top layer 206 made of an isolating material (e.g., oxide).

The stack 202 can extend in the second horizontal direction (e.g., the X direction) that is parallel to a top surface of the substrate 201 and perpendicular to the first horizontal direction (e.g., the Y direction). The conductive layers 204a and the isolating layers 204b can alternate in the vertical direction (e.g., Z direction) perpendicular to the second horizontal direction. The conductive layers 204a can be the same or different from each other in thickness, for example, ranging from 10-500 nm, e.g., about 35 nm. The isolating layers 204b can also be the same or different from each other in thickness, for example, ranging from 10-500 nm, e.g., about 25 nm. It should be noted that the number of the conductive layers 204a and the isolating layers 204b shown in FIG. 2A is for illustration only and that any suitable number of the conductive layers 204a and the isolating layers 204b can be included in the stack 202. The conductive layers 204a can include any suitable conducting material, such as tungsten (W), cobalt (Co), copper (Cu), aluminum (Al), polycrystalline silicon (polysilicon), titanium nitride (TiN), doped silicon, silicides, or any combination thereof. In some implementations, as shown in FIG. 2A, each conductive layer 204a can include an adhesive layer made of conductive adhesive material such as titanium nitride (TiN) surrounding the conductive material. The isolating layers 204b can include a dielectric material, such as silicon oxide, silicon nitride, silicon oxynitride, or any combination thereof. In some implementations, the isolating layers 204b can also include high-K dielectric materials, such as hafnium oxide, zirconium oxide, aluminum oxide, tantalum oxide, lanthanum oxide, or any combination thereof.

The semiconductor device 200 can include an array of channel structures 210 extending through the stack 202. In some implementations the channel structures 210 can be similar to, or same as, the channel structures 110 as shown in FIG. 1, of the semiconductor device 100. Each channel structure 210 can extend through the stack 202 along the Z direction. In some examples, the channel structure 210 can be in the shape of a cylinder or a pillar, and can include an outer layer 209a, a block layer 209f surrounded by the outer layer, a charge trapping layer (or a storage layer) surrounded by the block layer, a tunneling layer surrounded by the charge trapping layer, a channel layer 209c surrounded by the tunneling layer, and a core filler layer 209d surrounded by the channel layer 209c, and a channel plug 209e formed above the core filler layer 209d and being in contact with the channel layer 209c. In some implementations, the channel layer 209c can include silicon, such as amorphous silicon, polysilicon, or single crystalline silicon, the tunneling layer can include silicon oxide, silicon nitride, or any combination thereof, the blocking layer can include silicon oxide, silicon nitride, high-K dielectrics, or any combination thereof, and the charge trapping layer can include silicon nitride, silicon oxynitride, silicon, or any combination thereof. In some implementations, the tunneling layer, the charge trapping layer, and the blocking layer, collectively referred to as a memory film 209b, can include ONO dielectrics (silicon Oxide-silicon Nitride-silicon Oxide).

The semiconductor device 200 can include an isolating structure 212. The isolating structure 212 extends through the stack 202 along the Z direction and is spaced from the channel structure 210 along a horizontal direction (e.g., the Y direction) perpendicular to the Z direction. In some implementations, the isolating structure 212 can have an inner body 214 and an outer layer 216 that is at least partially between the inner body 214 and the stack 202 along the Y direction. In some implementations, the outer layer 216 of the isolating structure 212 includes an isolation material (e.g., SiO2), and the inner body 214 has a first end 214-1 and a second end 214-2 that are opposite to each other along the first direction. The conductive layers 204a and the isolation layers 204b of the stack 202 are connected to the outer layer 216 of the isolating structure 212 along the Y direction. In some implementations, the inner body 214 is filled with at least one semiconductor material extending continuously along the Z direction. In some implementations, the at least one semiconductor material filled in the inner body 214 of the isolating structure 212 has a polycrystalline structure, and the at least one semiconductor material extends seamlessly along the first direction. In some implementations, the isolating structure 212 can be similar to, or same as the gate line slit structure 118 of the semiconductor device 100 of FIG. 1.

The semiconductor device 200 can include at least one semiconductor layer 218 and one dielectric layer 219 stacked with the stack along the first direction. In some implementations, the isolating structure 212 extends into the at least one semiconductor layer 218 and one dielectric layer 219 along the Z direction. In some implementations, the outer layer 216 of the isolating structure 212 can include a first portion 217a and a second portion 217b along the first direction. The first portion 217a of the outer layer 216 of the isolating structure 212 is closer to the first end 214-1 of the inner body 214 than the second end 214-2 of the inner body 214 along the first direction. In some implementations, the first portion 217a of the outer layer 216 is between the inner body 214 and the semiconductor substrate 201. In some implementations, a portion of the first portion 217a of the outer layer 216 is between the inner body 214 and at least one semiconductor layer 218 and one dielectric layer 219. A remaining portion of the first portion 217a of the outer layer 216 is between the inner body 214 and the semiconductor substrate 201. The second portion 217b of the out layer 216 is between the inner body 214 and the stack 202 along the Y direction. In some implementations, a thickness of the first portion 217a of the outer layer 216 is greater than a thickness of the second portion 217b of the outer layer 216 along the Y direction. In some implementations, the thickness of the second portion 217b of the outer layer 216 is greater than 2 nm.

In some implementations, the at least one semiconductor material filled in the inner body 214 of the isolating structure 212 is an alloy of two or more semiconductor materials. In some implementations, the alloy of two or more semiconductor materials can be a combination of two or more semiconductors, e.g., elemental semiconductors such as Silicon (Si) and Germanium (Ge) or compound semiconductor such as Gallium Arsenide (GaAs) with Indium Arsenide (InAs) or Zinc Sulfide (ZnS) with Zinc Selenide (ZnSe). In some implementations, the alloy semiconductor includes Silicon-Germanium (SiGe), and the inner body 214 includes a core region 215a and a transition region 215b. In some implementations, the transition region 215b is at the first end 214-1 of the inner body 214. In some implementations, a concentration of Silicon (Si) in the alloy semiconductor in the transition region 215b is greater than a concentration of Si in the alloy semiconductor in the core region 215a. In some implementations, at least a portion of the transition region 215b is at the first end 214-1 of the inner body 214, and a remaining portion of the transition region 215b is between the core region 215a and the outer layer 216 along the Y direction. In some implementations, the remaining portion of the transition region 215b is closer to the first end 214-1 of the inner body 214 than the second end 214-2 of the inner body 214. In some implementations, in the core region 215a, a concentration of Ge in the alloy semiconductor is greater than 80%, and the concentration of Si in the alloy is smaller than 20%. In some implementations, in the transition region 215b, a concentration of Si in the alloy semiconductor is in a range between 20% and 28%. In some implementations, a thickness of the transition region 215b along the Y direction is associated with a dimension of the isolating structure, and a length of the transition region 215b along the Z direction is associated with a dimension of the isolating structure. In some implementations, a length of the inner body 214 along the Y direction is at least two times greater than the thickness of the transition region 215b along the Y direction. In some implementations, a length of the inner body 214 along the Y direction is at least three times greater than the length of the transition region 215b along the Z direction. In some implementations, an end 215b-1 of the transition region 215b is below a surface of the stack 202. In some implementations, an end 210-1 of the channel structure 210 is farther from the stack 202 than an end 212-1 of the isolating structure 212.

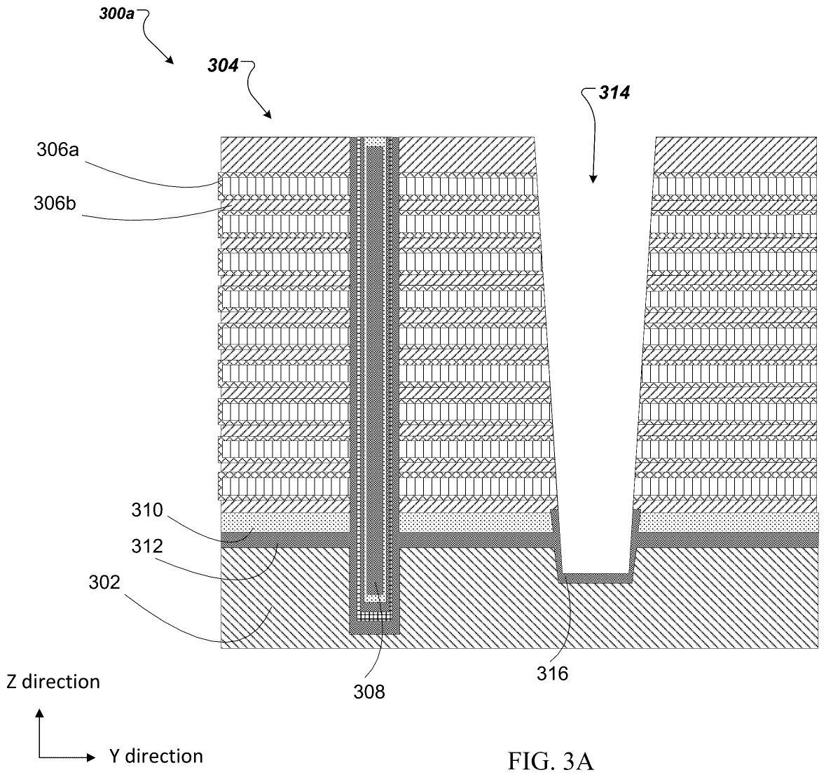

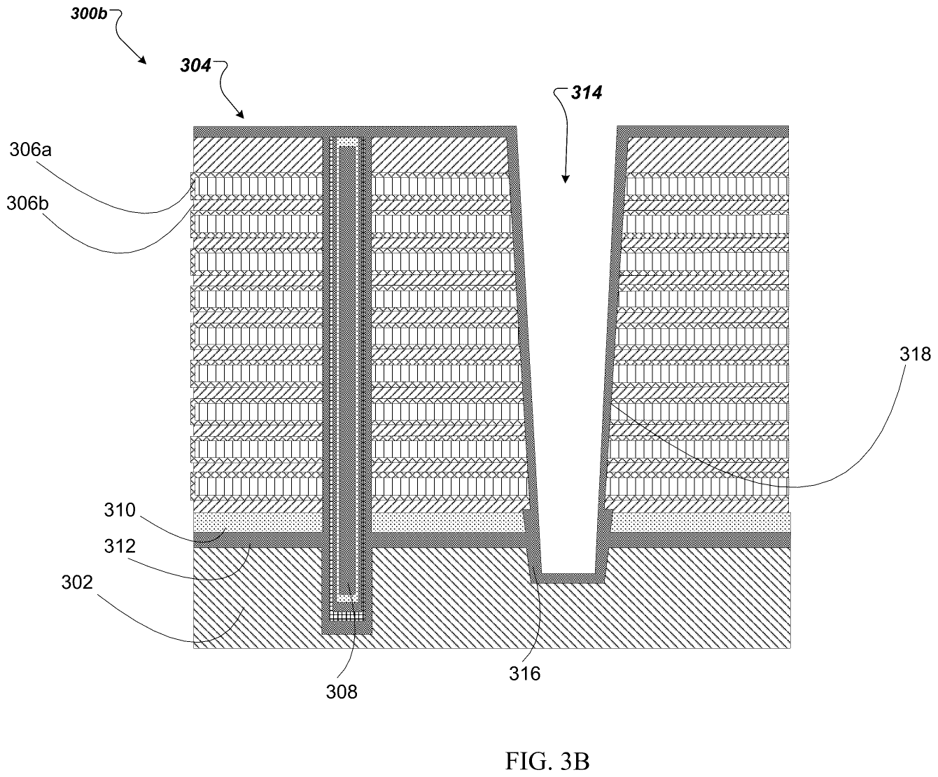

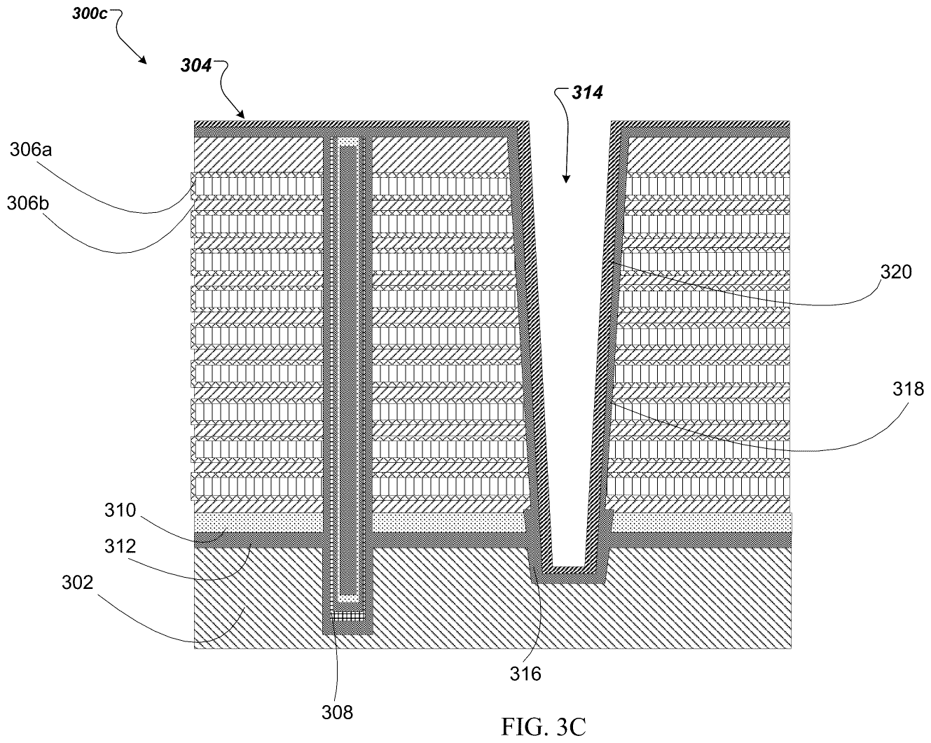

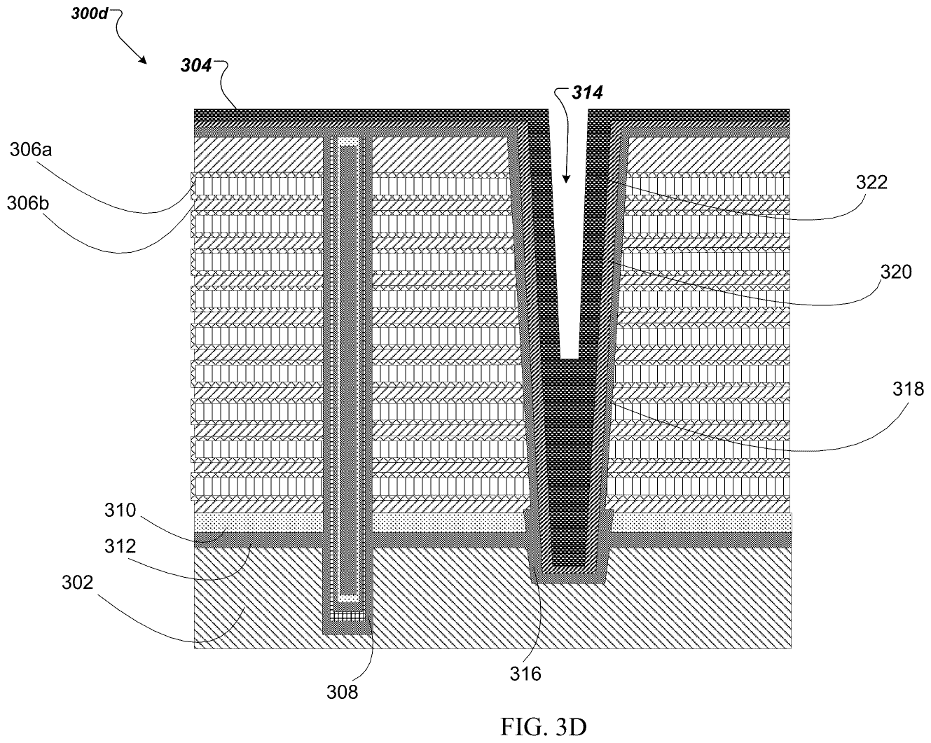

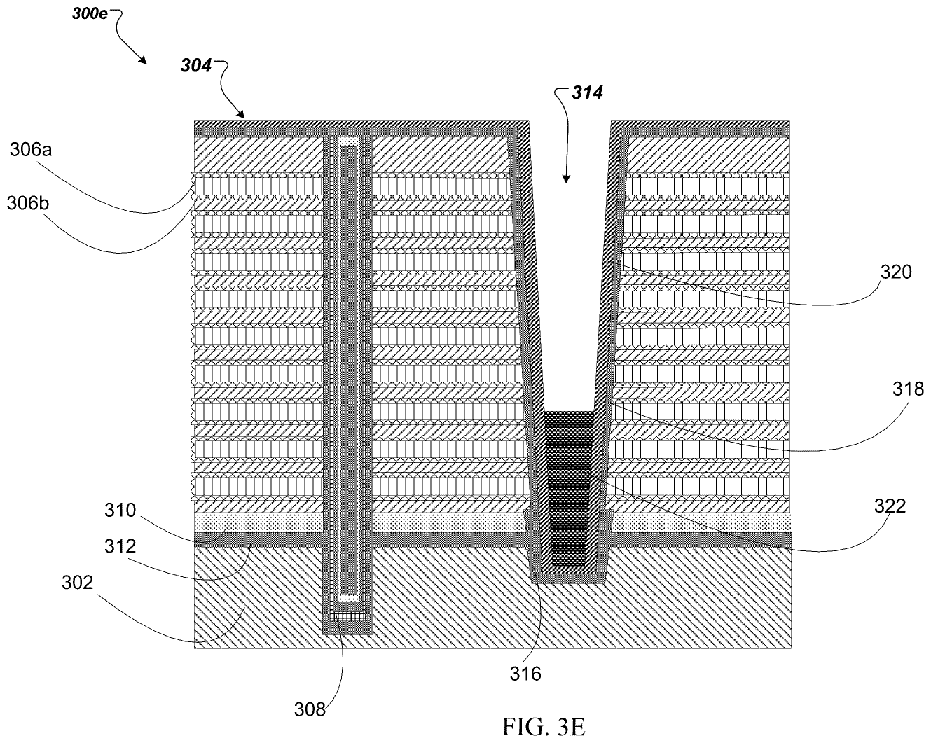

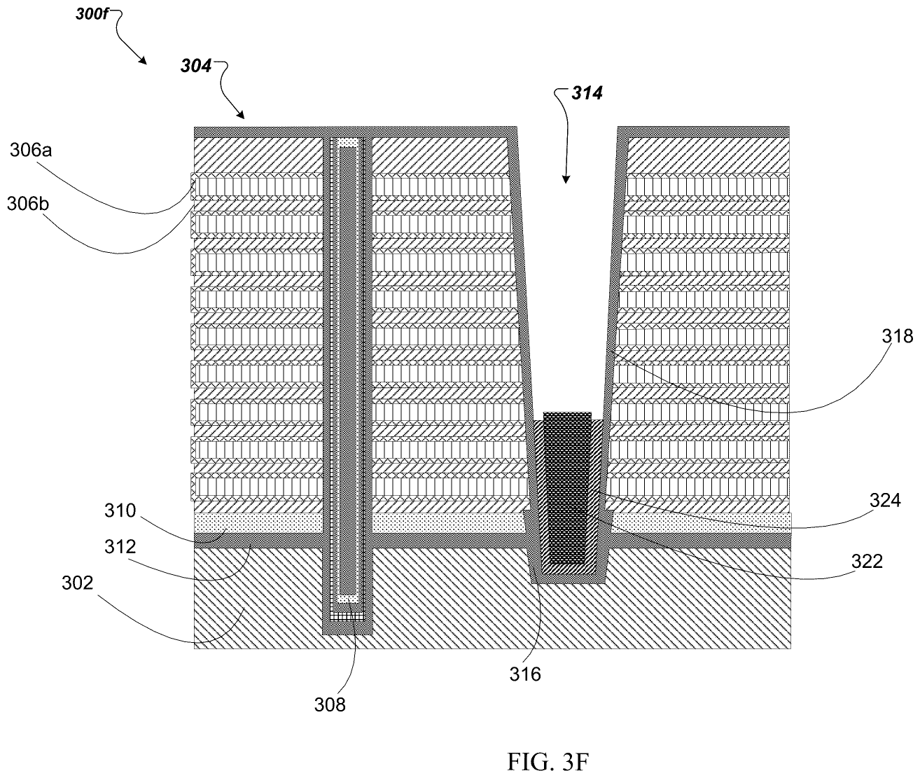

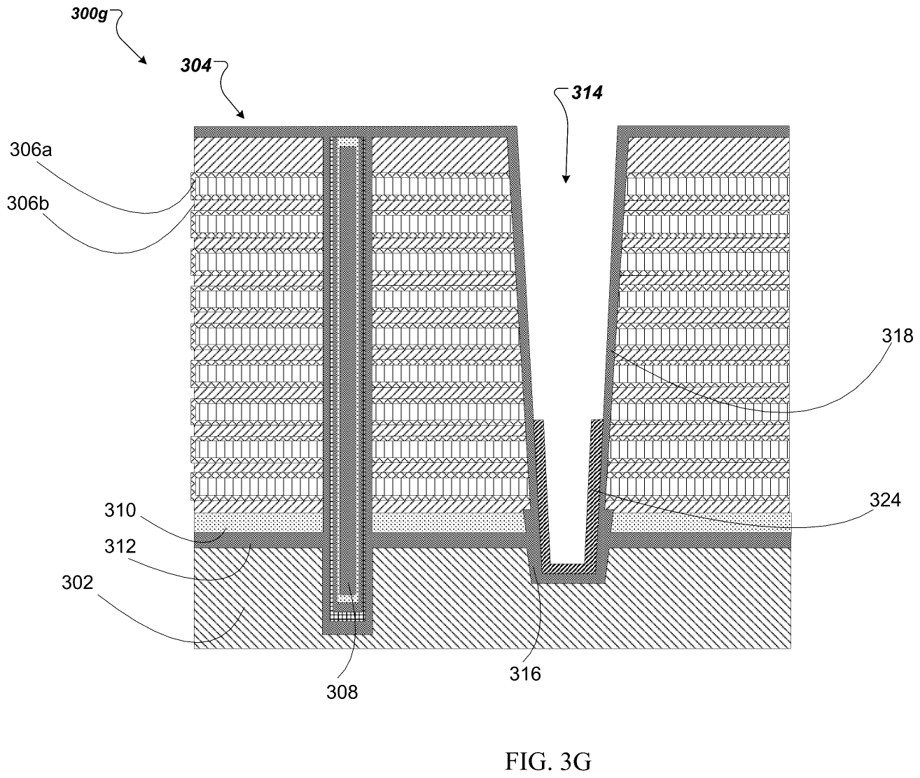

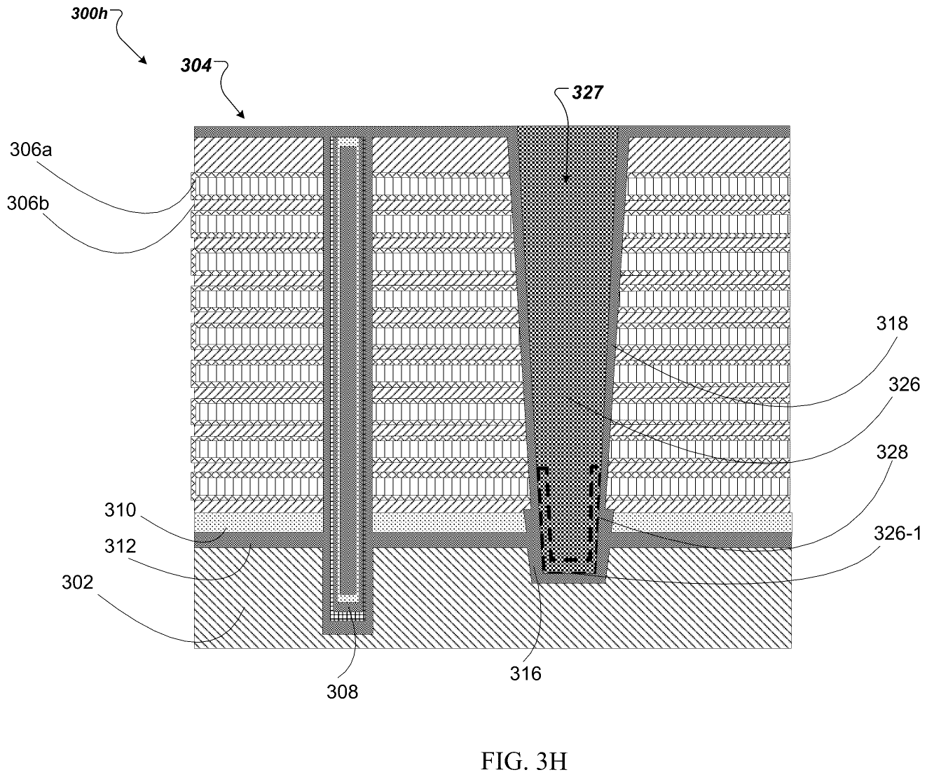

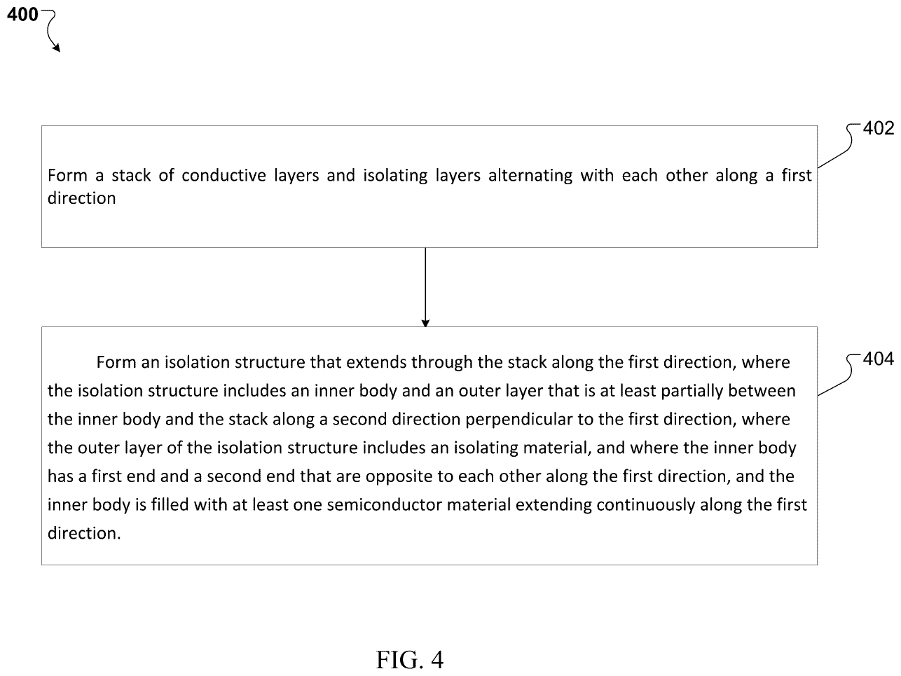

FIG. 2B illustrates a cross-sectional view of an example semiconductor device 200b. The semiconductor device 200b can be the semiconductor device 200 of FIG. 2A or a structure at an intermediate fabrication process of the semiconductor device 100 of FIG. 1. The semiconductor device 200b can be formed by methods and/or processes described with further details in FIG. 3A-3H, and/or FIG. 4.

In some implementations, a portion of the outer layer 209a, the block layer 209f and the memory film 209c that include the ONO dielectrics are removed from a side 210-1 of the channel structures. The semiconductor device 200b can further include a coupling-out layer 220 including a dielectric material. The channel layers 209c of the channel structures 210 of the semiconductor device 200b are connected to each other through the coupling-out layer 220 along the Z direction. In some implementations, the channel structures 210 of the semiconductor device 220b are coupled to conductive structures through the coupling-out structure 220 from the side 210-1 of the channel structures 210.

FIG. 2C illustrates a cross-sectional view of an example semiconductor device 200c. The semiconductor device 200c can be the semiconductor device 200 of FIG. 2A or a structure at an intermediate fabrication process of the semiconductor device 100 of FIG. 1. In some implementations, the semiconductor device 200c can be similar to the semiconductor device 200b of FIG. 2B, except a coupling out layer 224 of the semiconductor device 220c has a different structure compared to the coupling out layer 220 of the semiconductor device 200b. The semiconductor device 200b can be formed by methods and/or processes described with further details in FIG. 3A-3H, and/or FIG. 4.

In some implementations, the channel structures 210 of the semiconductor device 200c are coupled each other through a coupling-out layer 224 through the at least one semiconductor layer 218 and one dielectric layer 219 along the Y direction. In some implementations, the coupling-out layer 224 is connected to the channel layer 209c of the channel structure 210 along the Y direction. The coupling-out layer 224 can be similar to, or same as, the coupling out-structure 220, and can include one or more conductive layers, e.g., an inner metal layer like Tungsten (W) and an outer metal layer like TiN. In some implementations, the channel structures 210 of the semiconductor device 200c are coupled to conductive structures through the coupling-out layer 224 along the Y direction.

FIGS. 3A-3H illustrate an example process of fabricating a semiconductor device, such as the semiconductor device 100 as illustrated in FIG. 1 or semiconductor devices 200, 200b, and 200c as illustrated in FIGS. 2A-2C. FIGS. 3A-3H show cross-sectional views of example semiconductor structures at various stages of the fabrication process.

As shown in FIG. 3A, a semiconductor structure 300a is formed. The semiconductor structure 300a includes a substrate 302 and a stack 304 of dielectric layers 306a and isolating layers 306b that alternate with each other along a vertical direction (e.g., Z direction). The semiconductor structure 300a also includes a channel structure 308 that extends through the stack 304 and into the substrate 302 along the Z direction. In some implementations, the semiconductor structure 300a can include at least one semiconductor layer 310 and one dielectric layer 312 stacked with the stack along the Z direction. The semiconductor structure 300a can be formed by, for example, etching through the stack 304 into the semiconductor substrate 302 along the Z direction to form a trench 314. The semiconductor structure 300a can also include a first dielectric layer 316 in a portion of a trench structure. In some implementations, the first dielectric layer is formed through a thermal oxidation process that oxidize a semiconductor material of a portion of the semiconductor substrate 302 and a portion of the at least one semiconductor layer 310 to a dielectric material. The semiconductor structure 300a can also include conductive layers 306a. The conductive layers 306a of the stack 304 of the semiconductor structure 300a is formed by replacing the dielectric layers 306a of the stack 304 with a conductive material.

FIG. 3B illustrates a semiconductor structure 300b, which can be formed by depositing a second dielectric layer 318 on a sidewall of the trench 314 and a surface of the semiconductor structure 300a.

FIG. 3C illustrates a semiconductor structure 300c, which can be formed by depositing a semiconductor layer 320 in the trench 314 and on a surface of the semiconductor structure 300b. The semiconductor layer 320 can include a semiconductor material similar to, or same as one of the materials in the at least one semiconductor material filled in the inner body 214 of semiconductor device 200 of FIG. 2A. In some implementations, the at least one semiconductor materials is an alloy of two or more semiconductor materials. In some implementations, the alloy includes Silicon-Germanium (SiGe), and the semiconductor material of the semiconductor layer 320 is Si.

FIG. 3D illustrates a semiconductor structure 300d, which can be formed by depositing a sacrificial material in the trench 314 and on a surface of the semiconductor structure 300c to form a sacrificial structure 322. In some implementations, the sacrificial material is a photoresist material.

FIG. 3E illustrates a semiconductor structure 300e, which can be formed by removing a portion of the sacrificial structure 322 on a surface of the semiconductor structure 300d and in the trench 314 to expose a portion of the semiconductor layer 320.

FIG. 3F illustrates a semiconductor structure 300f, which can be formed by etching the exposed portion of the semiconductor layer 320 on a surface of the semiconductor substrate 302 and the trench 314, to form a seed layer 324.

FIG. 3G illustrates a semiconductor structure 300g, which can be formed by removing a remaining portion of the sacrificial structure 322.

FIG. 3H illustrates a semiconductor structure 300h, which can be formed by growing an alloy semiconductor in the trench 314 from the seed layer 324 to a surface of the stack 304 to form an inner body 326 of an isolating structure 327. The semiconductor structure 300h can be similar to, or same as, the semiconductor structure 200 of FIGS. 2A, 200b of FIG. 2B, or 200C of FIG. 2C. In some implementations, the alloy semiconductor can include two or more semiconductor materials, and a semiconductor material in the seed layer 324 is one of the two or more semiconductor materials of the alloy semiconductor. In some implementations, the alloy semiconductor filled in the trench 314 has a polycrystalline structure and extending continuously along the Z direction. In some implementations, the alloy semiconductor of the inner body 326 is formed through a low pressure chemical vapor deposition (LPCVD) process. In some implementations, the alloy semiconductor of the inner body 326 is diffused into the seed layer 324 during the LPCVD process to from a transition region 328 of the inner body. In some implementations, at least a portion of the transition region 328 is at a first end 326-1 of the inner body. In some implementations, a selectivity of the alloy semiconductor to grow on the seed layer 324 is higher than a selectivity of the alloy semiconductor to grow on the second dielectric layer 318. In some implementations, a remaining portion of the inner body defines a core region 329. In some implementations, the alloy semiconductor can be Silicon-Germanium (SiGe), where a concentration of Si in the alloy in the transition region 328 is greater than a concentration of Si in the alloy in the core region 329. In some implementations, a concentration of Ge in the alloy is greater than 80% and the concentration of Si in the alloy is smaller than 20% in the core region. In some implementations, in the transition region 328, a concentration of Si in the alloy is in a range between 20% and 28%.

FIG. 4 illustrates a flow chart of an example process 400. The process 400 can be performed to form a semiconductor device (e.g., the semiconductor device 200 illustrated by FIG. 2A, the semiconductor device 200b illustrated by FIG. 2B, or the semiconductor device 200c illustrated by FIG. 2C). The process 400 can be described in view of FIG. 3A-3H. The process 400 can include one or more steps of the fabrication process of forming the semiconductor structures in FIG. 3A-3H. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a stack (e.g., the stack 304 of FIG. 3A) of conductive layers (e.g., conductive layers 306a of FIG. 3A) and isolating layers (e.g., isolating layers 306b of FIG. 3A) alternating with each other along a first direction (e.g., the Z direction) is formed.

At operation 404, an isolating structure (e.g., the isolating structure 327 of FIG. 3H) that extends through the stack along the first direction is formed, where the isolating structure includes an inner body (e.g., the inner body 326 of FIG. 3H) and an outer layer (the outer layer 216 of FIG. 2A) that is at least partially between the inner body and the stack along a second direction (e.g., the Y direction) perpendicular to the first direction, where the outer layer of the isolating structure includes an isolating material, and where the inner body has a first end (e.g., the first end 214-1 of FIG. 2A) and a second end (e.g., the second end 214.2 of FIG. 2A) that are opposite to each other along the first direction, and the inner body is filled with at least one semiconductor material extending continuously along the first direction.

In some implementations, the operation further includes: providing an initial stack of dielectric layers and isolating layers alternating with each other on a semiconductor substrate (e.g., the semiconductor substrate 302 of FIG. 3A) along the first direction; etching through the initial stack into the semiconductor substrate along the first direction to from a trench (the trench 314 of FIG. 3A), where a first portion of the trench extends in the semiconductor substrate along the second direction, and a second portion of the trench extends in the stack along the second direction; forming a first dielectric layer (e.g., the first dielectric layer 316 of FIG. 3A) in the semiconductor substrate by thermal oxidation, where the first dielectric layer is in contact with the first portion of the trench; and forming conductive layers of the stack by replacing the dielectric layers of the initial stack with a conductive material.

In some implementations, the operation further includes: depositing a second dielectric layer (e.g., the second dielectric layer 318 of FIG. 3B) on a sidewall of the trench, where the second dielectric layer is deposited on the first dielectric layer to form the outer layer, where a first portion (the first portion 217a of FIG. 2A) of the outer layer is between the trench and semiconductor substrate along the second direction, and a second portion (e.g., the second portion 217b of FIG. 2A) of the outer layer is between the trench and the stack along the second direction, and where, along the second direction, a thickness of the second portion of the outer layer is greater than a thickness of the first portion of the outer layer.

In some implementations, the at least one semiconductor material is an alloy of two or more semiconductor materials, and where the operation further includes: depositing one of the semiconductor materials of the alloy in the trench to form a semiconductor layer (e.g., the semiconductor layer 320 of FIG. 3C); filling the first trench with a photoresist material; removing a portion of the photoresist material in the trench to expose a portion of the semiconductor layer; etching the exposed portion of the semiconductor layer in the trench; and removing a remaining portion of the photoresist material in the trench to form a seed layer (e.g., the seed layer 324 of FIG. 3F), where at least a portion of the seed layer is at the an end of the outer layer, and where the seed layer is closer to the semiconductor substrate than a surface of the stack along the first direction.

In some implementations, forming the isolating structure includes: forming the inner body by growing the alloy in the trench from the seed layer to the surface of the stack, where the alloy filled in the trench has a polycrystalline structure.

In some implementations, growing the alloy includes: depositing the alloy in the trench by low pressure chemical vapor deposition (LPCVD) process, where the alloy is diffused into the seed layer during the LPCVD process to form a transition region (e.g., the transition region 328 of FIG. 3H) of the inner body, and where at least a portion of the transition region is at the first end of the inner body.

In some implementations, a selectivity of the alloy to grow on the seed layer is higher than a selectivity of the alloy to grow on the outer layer of the isolating structure.

In some implementations, the operation further includes: forming a channel structure (e.g., the channel structure 308 of FIG. 3A) extending through the stack along the first direction, where the isolating structure is spaced from the channel structure along the second direction, and where, along the first direction, an end (the end 210-1 of FIG. 2A) of the channel structure is farther from a surface of the stack than an end (the end 212-1 of FIG. 2A) of the isolating structure.

In some implementations, channel structures are coupled to each other through a coupling-out layer (the coupling-out layer 220 of FIG. 2B) along the first direction, the operation further includes: removing a bottom portion of the semiconductor substrate and the one or more dielectric material of the channel structure along the first direction to expose the conductive material of the channel structure; and forming the coupling-out layer connected to the conductive material of the channel structure along the first direction, where the channel structures of the semiconductor device are coupled to each other through the coupling-out layer along the first direction.

In some implementations, the semiconductor device further includes including at least one semiconductor layer (e.g., the at least one semiconductor layer 218 of FIG. 2A) and one dielectric layer (the dielectric layer 219 of FIG. 2A) that are stacked with the stack along the first direction, where the operation further includes: forming a coupling-out layer (the coupling-out layer 224 of FIG. 2C) in contact with the conductive material of the channel structure by removing the at least one semiconductor layer and one dielectric layer and the one or more dielectric material of the channel structure along the second direction, where the channel structures are coupled to each other through the coupling-out layer along a second direction perpendicular to each other.

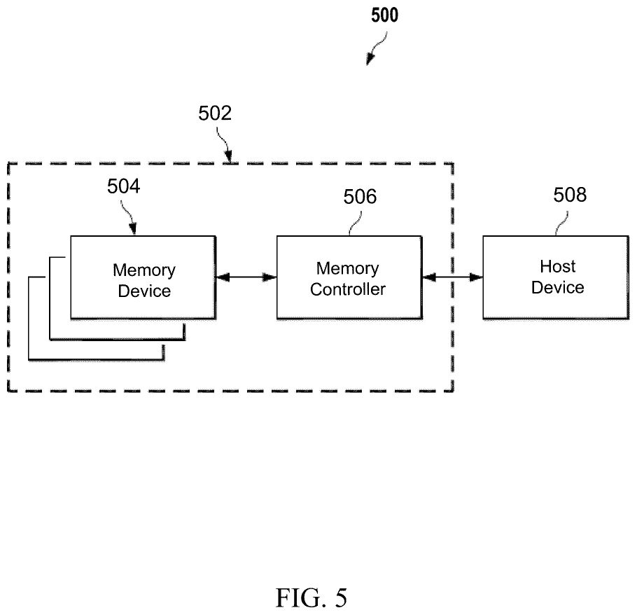

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed in the present disclosure, such as a memory device (e.g., a NAND Flash memory) as shown in FIG. 1 and FIG. 2A-2C. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g.,.+−.10%,.+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a stack of conductive layers and isolating layers alternating with each other along a first direction; and
an isolating structure that extends through the stack along the first direction, wherein the isolating structure comprises an inner body and an outer layer that is at least partially between the inner body and the stack along a second direction perpendicular to the first direction,
wherein the outer layer of the isolating structure comprises an isolating material, and
wherein the inner body has a first end and a second end that are opposite to each other along the first direction, and the inner body is filled with at least one semiconductor material extending continuously along the first direction.

2. The semiconductor device of claim 1, wherein the at least one semiconductor material filled in the inner body has a polycrystalline structure, and wherein the at least one semiconductor material extends seamlessly along the first direction.

3. The semiconductor device of claim 1, further comprising at least one additional layer stacked with the stack along the first direction, wherein the isolating structure extends into the at least one additional layer along the first direction,
wherein the outer layer comprises a first portion and a second portion along the first direction, the first portion being closer to the first end than the second end of the inner body, and
wherein the first portion of the outer layer is between the inner body and the at least one additional layer along the second direction, and the second portion of the outer layer is between the inner body and the stack along the second direction.

4. The semiconductor device of claim 3, wherein, along the second direction, a thickness of the first portion of the outer layer is greater than a thickness of the second portion of the outer layer.

5. The semiconductor device of claim 1, wherein the at least one semiconductor material is an alloy of two or more semiconductor materials.

6. The semiconductor device of claim 5, wherein the alloy comprises Silicon-Germanium (SiGe), and wherein the inner body comprises a core region and a transition region, wherein at least a portion of the transition region is at the first end of the inner body, wherein a concentration of Silicon (Si) in the alloy in the transition region is greater than a concentration of Silicon (Si) in the alloy in the core region.

7. The semiconductor device of claim 6, wherein in the core region, a concentration of Germanium (Ge) in the alloy is greater than 80%, and the concentration of Silicon (Si) in the alloy is smaller than 20%, and
wherein, in the transition region, a concentration of Silicon (Si) in the alloy is in a range between 20% and 28%.

8. The semiconductor device of claim 6, wherein the transition region has one or more characteristics comprising:
a thickness of the transition region along the second direction being associated with a dimension of the isolating structure, and
a length of the transition region of the inner body along the first direction being associated with a dimension of the isolating structure.

9. The semiconductor device of claim 1, further comprising:
a channel structure extending through the stack along the first direction, the isolating structure being spaced from the channel structure along the second direction,
wherein, along the first direction, an end of the channel structure is farther from the stack than an end of the isolating structure.

10. The semiconductor device of claim 9, wherein the channel structure is coupled to a conductive structure through a coupling-out structure from a bottom of the semiconductor device closer to the first end than the second end.

11. The semiconductor device of claim 9, further comprising at least one semiconductor layer and one dielectric layer that are stacked with the stack along the first direction,
wherein the channel structure is coupled to a conductive structure through a coupling-out structure through the semiconductor layer along the second direction.

12. A method of forming a semiconductor device, comprising:
forming a stack of conductive layers and isolating layers alternating with each other along a first direction; and
forming an isolating structure that extends through the stack along the first direction, wherein the isolating structure comprises an inner body and an outer layer that is at least partially between the inner body and the stack along a second direction perpendicular to the first direction,
wherein the outer layer of the isolating structure comprises an isolating material, and
wherein the inner body has a first end and a second end that are opposite to each other along the first direction, and the inner body is filled with at least one semiconductor material extending continuously along the first direction.

13. The method of claim 12, further comprising:
providing an initial stack of dielectric layers and isolating layers alternating with each other on a semiconductor substrate along the first direction;
etching through the initial stack into the semiconductor substrate along the first direction to from a trench, wherein a first portion of the trench extends in the semiconductor substrate along the second direction, and a second portion of the trench extends in the stack along the second direction;
forming a first dielectric layer in the semiconductor substrate by thermal oxidation, wherein the first dielectric layer is in contact with the first portion of the trench; and
forming conductive layers of the stack by replacing the dielectric layers of the initial stack with a conductive material.

14. The method of claim 13, further comprising:
depositing a second dielectric layer on a sidewall of the trench, wherein the second dielectric layer is deposited on the first dielectric layer to form the outer layer,
wherein a first portion of the outer layer is between the trench and semiconductor substrate along the second direction, and a second portion of the outer layer is between the trench and the stack along the second direction, and
wherein, along the second direction, a thickness of the second portion of the outer layer is greater than a thickness of the first portion of the outer layer.

15. The method of claim 14, wherein the at least one semiconductor material is an alloy of two or more semiconductor materials, and wherein the method further comprises:
depositing one of the semiconductor materials of the alloy in the trench to form a semiconductor layer;
filling the first trench with a photoresist material;
removing a portion of the photoresist material in the trench to expose a portion of the semiconductor layer;
etching the exposed portion of the semiconductor layer in the trench; and
removing a remaining portion of the photoresist material in the trench to form a seed layer, wherein at least a portion of the seed layer is at the an end of the outer layer, and wherein the seed layer is closer to the semiconductor substrate than a surface of the stack along the first direction.

16. The method of claim 15, wherein forming the isolating structure comprises:
forming the inner body by growing the alloy in the trench from the seed layer to the surface of the stack,
wherein the alloy filled in the trench has a polycrystalline structure.

17. The method of claim 16, wherein growing the alloy comprises:
depositing the alloy in the trench by low pressure chemical vapor deposition (LPCVD) process,
wherein the alloy is diffused into the seed layer during the LPCVD process to form a transition region of the inner body, and wherein at least a portion of the transition region is at the first end of the inner body.

18. The method of claim 17, wherein a selectivity of the alloy to grow on the seed layer is higher than a selectivity of the alloy to grow on the outer layer of the isolating structure.

19. The method of claim 12, further comprising:
forming a channel structure extending through the stack along the first direction, wherein the isolating structure is spaced from the channel structure along the second direction, and
wherein, along the first direction, an end of the channel structure is farther from a surface of the stack than an end of the isolating structure.

20. A memory system, comprising:
a memory device; and
a memory controller coupled to the memory device and configured to control the memory device,
wherein the memory device comprises:
a stack of conductive layers and isolating layers alternating with each other along a first direction; and
an isolating structure that extends through the stack along the first direction, wherein the isolating structure comprises an inner body and an outer layer that is at least partially between the inner body and the stack along a second direction perpendicular to the first direction,
wherein the outer layer of the isolating structure comprises an isolating material, and
wherein the inner body has a first end and a second end that are opposite to each other along the first direction, and the inner body is filled with at least one semiconductor material extending continuously along the first direction.
